(19) United States
(12) Patent Application Publication
(10) Pub. No.: US 2026/0123430 A1
(43) Pub. Date: Apr. 30, 2026

(54) SEMICONDUCTOR STRUCTURE BASED ON MULTI-FACE UNIT STRUCTURE

(71) Applicant: SAMSUNG ELECTRONICS CO., LTD., Suwon-si (KR)

(72) Inventors: Hyeokki HONG, Suwon-si (KR); Kitae PARK, Suwon-si (KR); Joonseong KANG, Suwon-si (KR); Mikyung KIM, Suwon-si (KR); Jonghan KIM, Suwon-si (KR); Chang-Woo SHIN, Suwon-si (KR); Takhyung LEE, Suwon-si (KR); Byungsu JUNG, Suwon-si (KR); Anes JU, Suwon-si (KR)

(73) Assignee: SAMSUNG ELECTRONICS CO., LTD., Suwon-si (KR)

(21) Appl. No.: 19/254,922

(22) Filed: Jun. 30, 2025

(30) Foreign Application Priority Data
Oct. 29, 2024 (KR) 10-2024-0150045

(51) Int. Cl. H01L 23/58

(52) U.S. Cl. CPC H10W 42/00

(57) ABSTRACT

A semiconductor structure may include: an operation structure including a first multi-face structure and operation chips, wherein the first multi-face structure include a first signal path, and the operation chips are on faces of the first multi-face structure and are connected to the first signal path; an interface structure including a second multi-face structure and interface chips, wherein the second multi-face structure includes a second signal path, and the interface chips are on faces of the second multi-face structure and are connected to the second signal path; and a multi-face connection structure that contacts a first connection face from among the faces of the first multi-face structure and a second connection face from among the faces of the second multi-face structure, wherein the multi-face connection structure includes a third signal path that is connected to the first signal path and the second signal path.

### CROSS-REFERENCE TO RELATED APPLICATION

This application claims priority from Korean Patent Application No. 10-2024-0150045, filed on Oct. 29, 2024, in the Korean Intellectual Property Office, the disclosure of which is incorporated herein by reference in its entirety.

### BACKGROUND

### 1. Field

Some example embodiments of the present disclosure relate to a semiconductor structure based on a multi-face unit structure.

### 2. Description of Related Art

The integration density of integrated circuits (e.g., operation circuits, memory circuits, etc.) has continued to increase. Recently, artificial intelligence (AI)-oriented integrated circuits have been developed with the advancement of AI. For example, operation circuits (e.g., AI accelerators) for data-intensive AI operations, such as deep learning, and high-performance memory (e.g., high bandwidth memory (HBM)) that support these operation circuits have emerged. For example, these operation circuits and high-performance memory may be used on a large scale in data centers. These operation circuits and high-performance memory may outperform conventional processors and memory in tasks such as training AI models or performing inference with them.

### SUMMARY

One or more example embodiments may address at least the above problems and/or disadvantages and other disadvantages not described above. Also, the example embodiments are not required to overcome the disadvantages described above, and an example embodiment may not overcome any of the problems described above.

According to some embodiments of the present disclosure, a semiconductor structure may include: at least one operation structure including a first multi-face structure and operation chips, wherein the first multi-face structure includes a first signal path, and the operation chips are on faces of the first multi-face structure and are connected to the first signal path; at least one interface structure including a second multi-face structure and interface chips, wherein the second multi-face structure includes a second signal path, and the interface chips are on faces of the second multi-face structure and are connected to the second signal path; and at least one multi-face connection structure that contacts a first connection face from among the faces of the first multi-face structure and a second connection face from among the faces of the second multi-face structure, wherein the at least one multi-face connection structure includes a third signal path that is connected to the first signal path of an operation structure, from among the at least one operation structure, and the second signal path of an interface structure, from among the at least one interface structure.

According to one or more embodiments of the present disclosure, the at least one operation structure is a plurality of operation structures, the at least one interface structure is a plurality of interface structures, the at least one multi-face connection structure is a plurality of multi-face connection structures, and the plurality of operation structures, the plurality of interface structures, and the plurality of multi-face connection structures form a repetitive three-dimensional pattern in the semiconductor structure.

According to one or more embodiments of the present disclosure, the repetitive three-dimensional pattern includes sub-patterns including the plurality of operation structures, the plurality of interface structures, and the plurality of multi-face connection structures in different combination ratios.

According to one or more embodiments of the present disclosure, the repetitive three-dimensional pattern includes: a first sub-pattern in which a first interface structure from among the plurality of interface structures is connected to one of the faces of a first multi-face connection structure from among the plurality of multi-face connection structures, and first operation structures from among the plurality of operation structures are connected to remaining faces, excluding the one, of the faces of the first multi-face connection structure; a second sub-pattern in which second interface structures from among the plurality of interface structures are connected to two of the faces of a second multi-face connection structure from among the plurality of multi-face connection structures, and second operation structures from among the plurality of operation structures are connected to remaining faces, excluding the two, of the faces of the second multi-face connection structure; a third sub-pattern in which third interface structures from among the plurality of interface structures are connected to all faces of a third multi-face connection structure from among the plurality of multi-face connection structures; and a fourth sub-pattern in which a fourth operation structure from among the plurality of operation structures is connected to one of faces of a fourth multi-face connection structure from among the plurality of multi-face connection structures, and fourth interface structures from among the plurality of interface structures are connected to remaining faces, excluding the one, of the faces of the fourth multi-face connection structure.

According to one or more embodiments of the present disclosure, the semiconductor structure further includes a substrate, wherein one or more from among the plurality of operation structures, the plurality of interface structures, and the plurality of multi-face connection structures are connected to the substrate.

According to one or more embodiments of the present disclosure, the semiconductor structure further includes a first substrate region and a second substrate region, wherein a first structure from among the plurality of operation structures, the plurality of interface structures, and the plurality of multi-face connection structures is connected to the first substrate region, wherein a second structure from among the plurality of operation structures, the plurality of interface structures, and the plurality of multi-face connection structures is connected to the second substrate region, and wherein the first structure is configured to receive first data through the first substrate region, and the second structure is configured to output second data to the second substrate region.

According to one or more embodiments of the present disclosure, the semiconductor structure further includes a cooling tunnel in a space between the plurality of operation structures, the plurality of interface structures, and the plurality of multi-face connection structures.

According to one or more embodiments of the present disclosure, the operation chips are connected to the first connection face through the first signal path, the interface chips are connected to the second connection face through the second signal path, and the operation chips are connected to the interface chips through the first signal path, the second signal path, and the third signal path.

According to one or more embodiments of the present disclosure, one or more from among the first signal path, the second signal path, and the third signal path include one or more from among a wired path, a wireless path, and an optical path.

According to one or more embodiments of the present disclosure, the operation chips are configured to perform one or more from among an operation function and a memory function, and the interface chips are configured to perform one or more from among a communication function and a power function.

According to one or more embodiments of the present disclosure, the first multi-face structure, the second multi-face structure, and the at least one multi-face connection structure each have a cube shape.

According to embodiments of the present disclosure, a semiconductor package may be provided and include: at least one substrate; and a semiconductor structure including operation structures, interface structures, and multi-face connection structures, wherein one or more from among the operation structures, the interface structures, and the multi-face connection structures are connected to a substrate, wherein the operation structures, the interface structures, and the multi-face connection structures form a repetitive three-dimensional pattern, wherein an operation structure from among the operation structures includes a first multi-face structure and operation chips on faces of the first multi-face structure, wherein an interface structure from among the interface structures includes a second multi-face structure and interface chips that are on faces of the second multi-face structure, and wherein a multi-face connection structure from among the multi-face connection structures is connected to the operation structure and the interface structure through a first connection face from among the faces of the first multi-face structure and a second connection face from among the faces of the second multi-face structure.

According to one or more embodiments of the present disclosure, the repetitive three-dimensional pattern includes sub-patterns including the operation structures, the interface structures, and the multi-face connection structures in different combination ratios.

According to one or more embodiments of the present disclosure, the repetitive three-dimensional pattern includes: a first sub-pattern in which a first interface structure from among the interface structures is connected to one of the faces of a first multi-face connection structure from among the multi-face connection structures, and first operation structures from among the operation structures are connected to remaining faces, excluding the one, of the faces of the first multi-face connection structure; a second sub-pattern in which second interface structures from among the interface structures are connected to two of the faces of a second multi-face connection structure from among the multi-face connection structures, and second operation structures from among the operation structures are connected to remaining faces, excluding the two, of the faces of the second multi-face connection structure; a third sub-pattern in which third interface structures from among the interface structures are connected to all faces of a third multi-face connection structure from among the multi-face connection structures; and a fourth sub-pattern in which a fourth operation structure from among the operation structures is connected to one of faces of a fourth multi-face connection structure from among the multi-face connection structures, and fourth interface structures from among the interface structures are connected to remaining faces, excluding the one, of the faces of the fourth multi-face connection structure.

According to one or more embodiments of the present disclosure, a first structure from among the operation structures, the interface structures, and the multi-face connection structures is connected to a first substrate region of the at least one substrate, and a second structure from among the operation structures, the interface structures, and the multi-face connection structures is connected to a second substrate region of the at least one substrate, wherein the first structure is configured to receive first data through the first substrate region, and the second structure is configured to output second data to the second substrate region.

According to one or more embodiments of the present disclosure, the semiconductor package further includes a cooling tunnel in a space between the operation structures, the interface structures, and the multi-face connection structures.

According to one or more embodiments of the present disclosure, the first multi-face structure includes a first signal path that is connected to the operation chips, the second multi-face structure includes a second signal path that is connected to the interface chips, and the multi-face connection structure includes a third signal path.

According to one or more embodiments of the present disclosure, the operation chips are connected to the first connection face through the first signal path, the interface chips are connected to the second connection face through the second signal path, and the operation chips are connected to the interface chips through the first signal path, the second signal path, and the third signal path.

According to one or more embodiments of the present disclosure, one or more from among the first signal path, the second signal path, and the third signal path include one or more from among a wired path, a wireless path, and an optical path.

According to embodiments of the present disclosure, a semiconductor structure may be provided and include: a first operation structure including a first multi-face structure and first operation chips, wherein the first multi-face structure includes a first signal path, and the first operation chips are on faces of the first multi-face structure and are connected to the first signal path; a second operation structure including a second multi-face structure and second operation chips, wherein the second multi-face structure includes a second signal path, and the second operation chips are on faces of the second multi-face structure and are connected to the second signal path; and a multi-face connection structure that contacts a first connection face from among the faces of the first multi-face structure and a second connection face from among the faces of the second multi-face structure, wherein the multi-face connection structure includes a third signal path that is connected to the first signal path and the second signal path.

### BRIEF DESCRIPTION OF DRAWINGS

The above and/or other aspects will be more apparent by describing certain example embodiments, taken in conjunction with the accompanying drawings, in which:

FIG. 1 is a diagram illustrating an example of a fractal structure and a general plane structure, according to an embodiment;

FIG. 2 is a diagram illustrating an example of expandability of a fractal structure, according to an embodiment;

FIG. 3 is a diagram illustrating an example of a fractal structure, a general plane structure, a general stack structure, and a general three-dimensional structure, according to an embodiment;

FIG. 4 is a diagram illustrating an example of a configuration and a structure of a unit structure, according to an embodiment;

FIG. 5 is a diagram illustrating an example of a production process of multi-face structures, according to an embodiment;

FIG. 6 is a diagram illustrating an example of a production process of a unit structure, according to an embodiment;

FIG. 7 is a diagram illustrating an example of a semiconductor structure based on various types of unit structures, according to an embodiment;

FIGS. 8 and 9 are diagrams each illustrating an example of a configuration and a structure of a semiconductor package, according to an embodiment;

FIG. 10 is a diagram illustrating an example of a cooling tunnel, according to an embodiment;

FIGS. 11 and 12 are diagrams each illustrating an example of sub-patterns of a repetitive three-dimensional pattern, according to an embodiment;

FIG. 13 is a diagram illustrating an example of multi-connection between a semiconductor structure and a substrate, according to an embodiment;

FIG. 14 is a diagram illustrating an example of semiconductor structures arranged on both sides of a substrate, according to an embodiment;

FIG. 15 is a diagram illustrating an example of a semiconductor structure connected to a plurality of substrate regions, according to an embodiment;

FIG. 16 is a diagram illustrating an example of a unit structure including an optical signal path, according to an embodiment; and

FIG. 17 is a diagram illustrating an example of a configuration of an electronic device, according to an embodiment.

### DETAILED DESCRIPTION

The following detailed structural or functional description is provided as an example only and various alterations and modifications may be made to embodiments of the present disclosure. The present disclosure is not limited to the example embodiments described herein, and should be understood to include all changes, equivalents, and replacements within the spirit and scope of the present disclosure.

Terms, such as “first,” “second,” and the like, may be used herein to describe various components. Each of these terms is not used to define an essence, order, or sequence of a corresponding component but used merely to distinguish the corresponding component from other component(s). For example, a first component may be referred to as a second component, and similarly the second component may also be referred to as the first component.

It should be noted that if it is described that one component is “connected,” “coupled,” or “joined” to another component, a third component may be “connected,” “coupled,” and “joined” between the first and second components, although the first component may be directly connected, coupled, or joined to the second component.

The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “at least one of A and B,” “at least one of A, B, or C,” and the like, each of which may include any one of the items listed together in the corresponding one of the phrases, or all possible combinations thereof.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art and are not to be interpreted in an idealized or overly formal sense unless expressly so defined herein.

Hereinafter, non-limiting example embodiments of the present disclosure will be described in detail with reference to the accompanying drawings. When describing the example embodiments with reference to the accompanying drawings, like reference numerals refer to like elements, and a repeated description related thereto may be omitted.

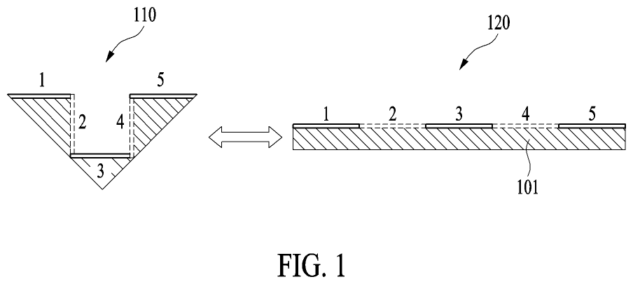

FIG. 1 is a diagram illustrating an example of a fractal structure and a general plane structure, according to an embodiment. Referring to FIG. 1, a specific bent angle may be formed between the first to fifth chips 1 to 5 in a fractal structure 110. For example, the specific bent angle may be formed between neighboring chips (e.g., the first chip 1 and the second chip 2) among the first to fifth chips 1 to 5. In a plane structure 120, the first to fifth chips 1 to 5 may be arranged without any bent angle. For example, a horizontal angle may be formed between neighboring chips. For example, the horizontal angle may be 180 degrees. A bent angle may be any angle such as, for example, 30 to 150 degrees, other than 180 degrees, but examples are not limited thereto. FIG. 1 illustrates the example of the bent angle being 90 degrees.

A substrate 101 may have a plane shape in the plane structure 120. The substrate 101 may have an appropriate shape for supporting the first to fifth chips 1 to 5 in the fractal structure 110 and connecting the first to fifth chips 1 to 5. FIG. 1 illustrates an example of the substrate 101 having a shape of continuous triangular prisms, but examples are not limited thereto. For example, as the number of chips increases, the substrate 101 may have a shape of continuous hexahedrons (e.g., cubes) or various polyhedrons, such as an octahedron.

According to an embodiment, a semiconductor structure based on the fractal structure 110 may be provided. Recently, the integration density of integrated circuits has been continuously increasing. The increasing integration density may involve power concentration per area and heat issues in an information transmission process for the operation of chips. A multi-stack structure based on wire-bonding, a multi-stack structure based on a through silicon via (TSV), a multi-stack structure based on an interposer, or a micro-cooling structure may be used, but there may be a limitation due to the plane structure 120. According to an embodiment, using the fractal structure 110 may lead to a reduced distance between chips and improved data transmission efficiency between chips. According to an embodiment, securing a space between chips in the fractal structure 110 may enable efficient cooling of the chips. According to an embodiment, efficient data transmission and efficient cooling using the fractal structure 110 may lead to improved power efficiency for data processing and cooling and reduced heat issues.

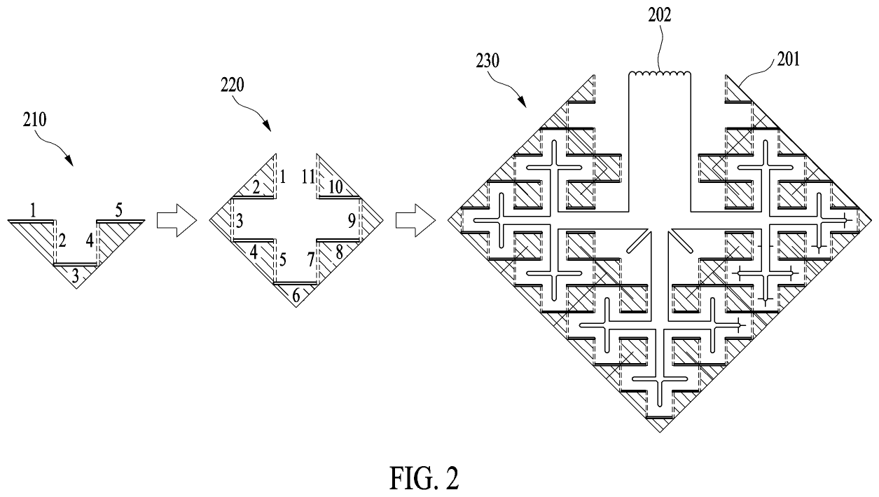

FIG. 2 is a diagram illustrating an example of the expandability of a fractal structure, according to an embodiment. Referring to FIG. 2, a first fractal structure 210 including first to fifth chips 1 to 5 may be extended to a second fractal structure 220 including first to eleventh chips 1 to 11. If the second fractal structure 220 is further expanded, a third fractal structure 230 may be derived. The continuous triangular prism shape of the second fractal structure 220 may be extended to a continuous hexahedral shape. However, a hexahedron is just an example, and various polyhedral structures may be used for the third fractal structure 230. The third fractal structure 230 may include a signal path 201 and a cooling space 202. The signal path 201 may be used to connect chips, and the cooling space 202 may be used to cool the chips. According to an embodiment, efficient data transmission and efficient cooling may be achieved by using a semiconductor structure based on a fractal structure, such as the first to third fractal structures 210 to 230.

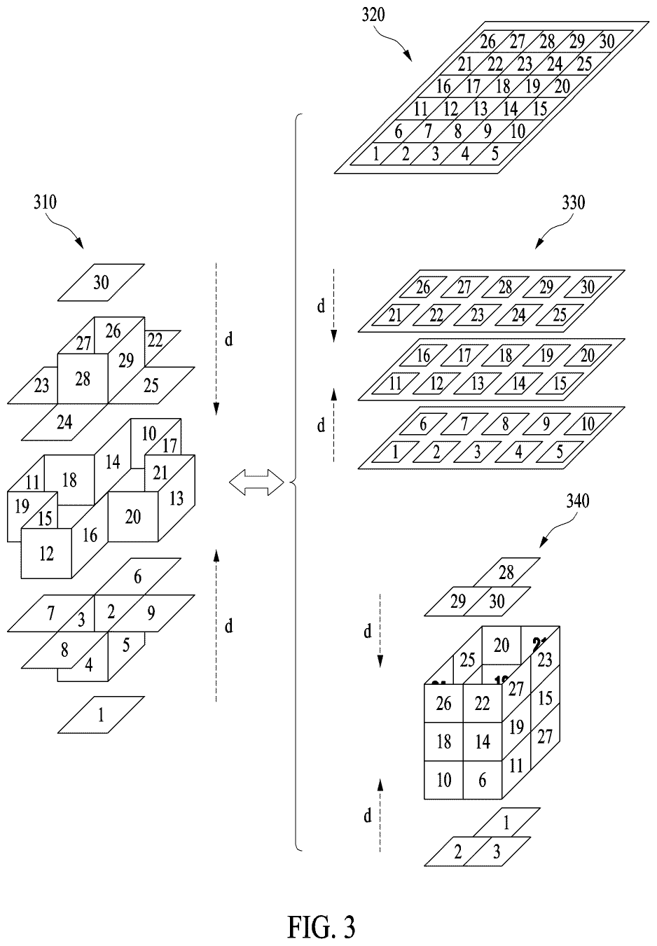

FIG. 3 is a diagram illustrating an example of a fractal structure, a general plane structure, a general stack structure, and a general three-dimensional structure, according to an embodiment. Referring to FIG. 3, first to thirtieth chips 1 to 30 may be arranged in a fractal structure 310, a plane structure 320, a stack structure 330, and a three-dimensional structure 340. For convenience, the fractal structure 310, the stack structure 330, and the three-dimensional structure 340 are illustrated as several layers being separated from one another. Layers of the fractal structure 310, the stack structure 330, and the three-dimensional structure 340 may be assembled along a direction d. The three-dimensional structure 340 is not a plane structure, like the fractal structure 310, but may have fewer bent areas than those of the fractal structure 310 and may occupy a larger volume than a volume of the fractal structure 310.

The fractal structure 310 may exhibit better indicators in terms of a chip distance, a volume, and a substrate-occupied area, compared to the plane structure 320, the stack structure 330, and the three-dimensional structure 340. For example, the chip distance may be measured as an average distance between the first to thirtieth chips 1 to 30. The substrate-occupied area may be measured as an area where the first to thirtieth chips 1 to 30 contact the substrate. A minimum chip distance of the fractal structure 310 may enable the achieving of efficient data transmission and efficient cooling. A minimum substrate-occupied area may enable the securing of a space where other devices may be connected to the substrate. In the fractal structure 310, an internal operation between the first to thirtieth chips 1 to 30 may be mainly performed, and the connection with other devices through the substrate may not be required.

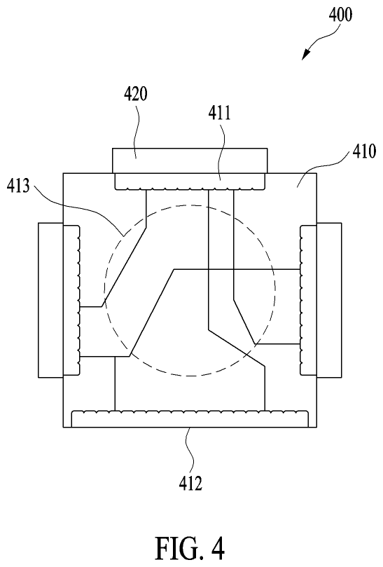

FIG. 4 is a diagram illustrating an example of a configuration and a structure of a unit structure, according to an embodiment. Referring to FIG. 4, a unit structure 400 may include a multi-face structure 410 and a chip 420. In an embodiment, a fractal structure may be implemented based on the unit structure 400 of FIG. 4.

The multi-face structure 410 may have a polyhedral shape. Although the multi-face structure 410 is illustrated as having a hexahedral shape (e.g., a cube), examples are not limited thereto. For example, the multi-face structure 410 may have various polyhedral shapes, such as an octahedron. A chip region 411 and/or a connection face may be formed on the faces of the multi-face structure 410. The chip 420 may be connected to the chip region 411. A connection face 412 may be used to connect with other multi-face structures or substrates.

The multi-face structure 410 may physically support one or more of chips, other unit structures, and substrates. A material used for a substrate (e.g., a printed circuit board (PCB) or an interposer) may be applied to a substrate of the multi-face structure 410. For example, various materials, such as paper phenolic (FR-2, FR-3, etc.), epoxy (FR-4, FR-5, G-2, G-11, etc.), polyamide, bismaleimide triazine (BT), metal, Teflon, ceramic, and halogen-free may be used, but examples are not limited thereto. For example, when the multi-face structure 410 is connected to a substrate, the multi-face structure 410 may serve as an interposer.

The multi-face structure 410 may provide a signal path 413 for the chip 420. The multi-face structure 410 may include the signal path 413 therein. The signal path 413 may be used to transmit signals between chips of the unit structure 400 and other structures. The signal path 413 may be used to transmit signals between such chips and external devices. The signal transmission between chips and external devices may be performed through a substrate.

The signal path 413 may include one or more from among a wired path, a wireless path, and an optical path. A material for the signal path 413 may be applied to the signal path 413 of the multi-face structure 410. For example, the wired path may be implemented with a metal material (e.g., copper), but examples are not limited thereto. The wireless path may provide a wireless connection path for a specific frequency. The optical path may include a micro-reflector or an optical fiber to transmit optical signals, but examples are not limited thereto.

Various types of chips may be connected to the unit structure 400. For example, the chips may include an operation chip or an interface chip. An operation chip may perform one or more of an operation function and a memory function, but examples are not limited thereto. For example, the operation chip may include an artificial intelligence (AI) accelerator for an AI operation. An interface chip may perform one or more of a communication function and a power function, but examples are not limited thereto. Each chip may be implemented in various structures. For example, each chip may be implemented in a multi-stack structure using wire bonding, a TSV, an interposer, or the like.

An operation chip may perform one or more from among a communication function and a power function other than an operation function and a memory function, but the main function of the operation chip may be one or more from among an operation function and a memory function. An interface chip may perform one or more from among an operation function and a memory function other than a communication function and a power function, but the main function of the interface chip may be one or more from among a communication function and a power function.

The unit structure 400 may have various types depending on its role within a semiconductor structure. The semiconductor structure may include unit structures, such as the unit structure 400. For example, each unit structure may correspond to one from among an operation structure, an interface structure, and a multi-face connection structure, but examples are not limited thereto. The main function of an operation structure may be an operation, the main function of an interface structure may be an interface, and the main function of a multi-face connection structure may be a connection.

An operation structure may include operation chips. The operation structure may include interface chips other than the operation chips, but the main function of the operation structure may be an operation. An interface structure may include interface chips. The interface structure may include operation chips other than the interface chips, but the main function of the interface structure may be an interface. A multi-face connection structure may not include chips. The multi-face connection structure may connect an operation structure, an interface structure, and a substrate to one another. The multi-face connection structure may include chips, but the main function of the multi-face connection structure may be to connect.

A semiconductor structure may include operation structures, interface structures, and multi-face connection structures. The operation structures, the interface structures, and the multi-face connection structures may form a repetitive three-dimensional pattern in the semiconductor structure. The repetitive three-dimensional pattern may be based on a fractal structure. The repetitive three-dimensional pattern may include sub-patterns including the operation structures, the interface structures, and the multi-face connection structures in different combination ratios.

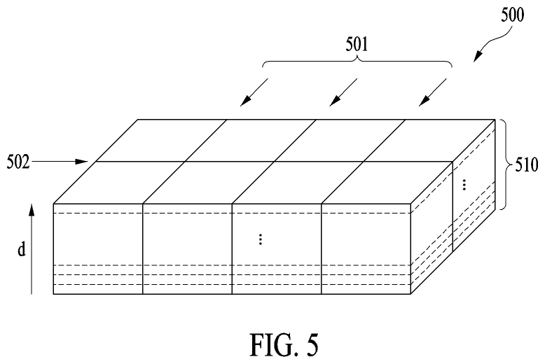

FIG. 5 is a diagram illustrating an example of a production process of multi-face structures, according to an embodiment. Referring to FIG. 5, layers 510 may be stacked along the direction d to produce multi-face structures 500. The multi-face structures 500 may be thicker than a general substrate. For example, the multi-face structures 500 may have a hexahedral shape, and the thickness in the direction d of a hexahedron may be thicker than that of a general substrate. The layers 510 may be stacked to secure the thickness of a hexahedron.

If the thickness is secured with the layers 510 being stacked, the multi-face structures 500 may be produced by cutting the layers 510 along cut faces 501 and 502. For example, thousands of layers 510 may be stacked to obtain a required thickness, but examples are not limited thereto. A production process of a substrate (e.g., a PCB, an interposer, etc.) may be applied to the process of stacking each of the layers 510, but examples are not limited thereto.

In the stacking process of the layers 510, a material used for a substrate may be applied to a substrate of the layers 510. In the stacking process of the layers 510, a material suitable for the type of signal path may be applied to a signal path of the layers 510. For example, a metal material may be applied to a wired path, a design to transmit a wireless signal may be applied to a wireless path, and a micro-reflector, an optical fiber, or the like may be applied to an optical path.

In the stacking process of the layers 510, a chip region and a connection face may be formed in the multi-face structures 500. Once the production of the multi-face structures 500 is completed, a separately produced chip may be connected to the chip region. The multi-face structures 500 may be connected to one another through the connection face of the multi-face structures 500.

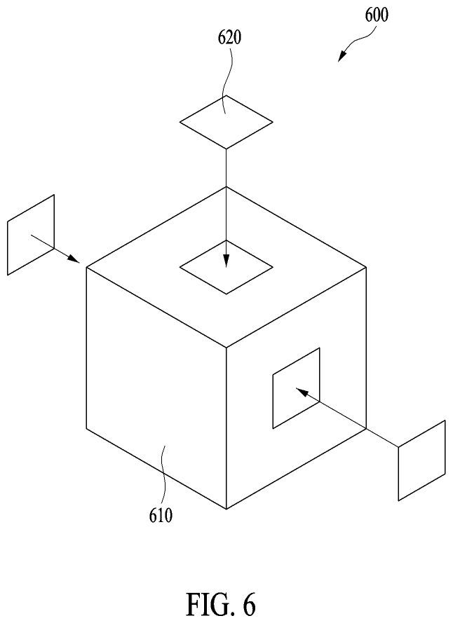

FIG. 6 is a diagram illustrating an example of a production process of a unit structure, according to an embodiment. Referring to FIG. 6, in a production process of a multi-face structure 610, a chip region and a connection face of the multi-face structure 610 may be formed. A chip 620 may be connected to the chip region of the multi-face structure 610.

Multi-face structures may be mass-produced through production processes. A multi-face structure for an operation structure, a multi-face structure for an interface structure, and a multi-face structure for a multi-face connection structure may be different from one another. The production processes of the multi-face structures may be divided depending on the type of chip used in each multi-face structure or a connection method between the multi-face structures. Various types of multi-face structures may be mass-produced through separate production processes. Chips may be mass-produced through a production process different from the production processes of the multi-face structures. The mass-produced chips may be connected to chip regions of the mass-produced multi-face structures.

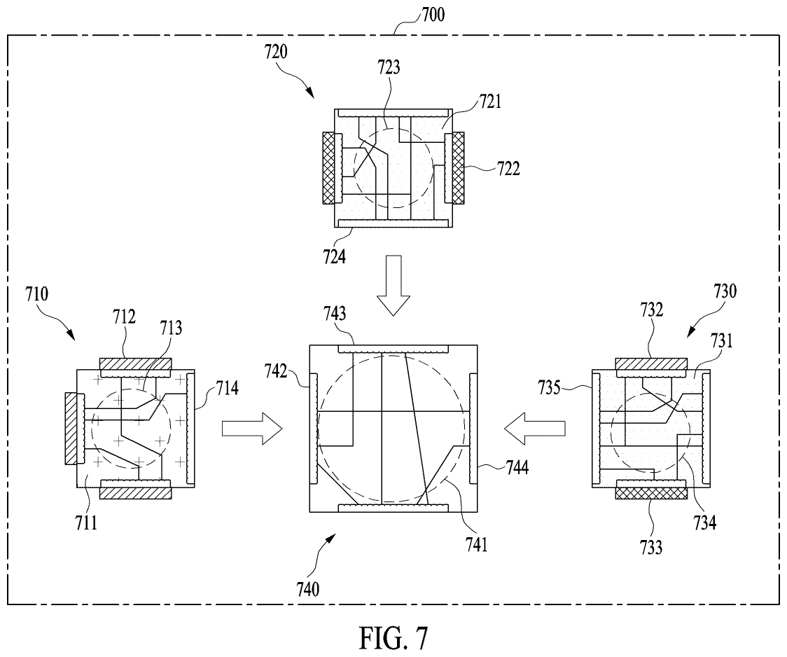

FIG. 7 is a diagram illustrating an example of a semiconductor structure based on various types of unit structures, according to an embodiment. Referring to FIG. 7, a semiconductor structure 700 may include an operation structure 710, a first interface structure 720, a second interface structure 730, and a multi-face connection structure 740.

The operation structure 710 may include a multi-face structure 711 and an operation chip 712. A signal path 713 may be formed inside the multi-face structure 711. The operation chip 712 may be arranged on a face (e.g., a chip region) of the multi-face structure 711 and may be connected to the signal path 713. The first interface structure 720 may include a multi-face structure 721 and an interface chip 722. The interface chip 722 may be arranged on a face (e.g., a chip region) of the multi-face structure 721 and may be connected to a signal path 723. The signal path 723 may be formed inside the multi-face structure 721. The second interface structure 730 may include a multi-face structure 731, an operation chip 732, and an interface chip 733. The second interface structure 730 includes the operation chip 732, but the main function of the second interface structure 730 may be an interface function. A signal path 734 may be formed inside the multi-face structure 721. The operation chip 732 and the interface chip 722 may be arranged on faces (e.g., chip regions) of the multi-face structure 731 and may be connected to the signal path 734.

A signal path 741 may be formed inside the multi-face connection structure 740. A connection face 742 (e.g., a connection surface) of the multi-face connection structure 740 may contact a connection face 714 among the faces of the operation structure 710. A connection face 743 of the multi-face connection structure 740 may contact a connection face 724 among the faces of the first interface structure 720. A connection face 744 of the multi-face connection structure 740 may contact a connection face 735 among the faces of the second interface structure 730. As the connection faces 742, 743, and 744 contact the connection faces 714, 724, and 735, respectively, the multi-face connection structure 740 may be connected to the operation structure 710, the first interface structure 720, and the second interface structure 730. The multi-face connection structure 740 may connect the signal path 741 to the signal paths 713, 723, and 734 based on each contact.

The operation chip 712 may be connected to the connection face 714 through the signal path 713, and the interface chip 722 may be connected to the connection face 724 through the signal path 723. As the multi-face connection structure 740 contacts the connection face 714 and the connection face 724, the operation chip 712 may be connected to the interface chip 722 through the signal path 713, the signal path 741, and the signal path 723. One or more of the signal paths 713, 723, 734, and 741 may include one or more of a wired path, a wireless path, and an optical path. The multi-face structures 711 and 721 and the multi-face connection structure 740 may have a cube shape.

The semiconductor structure 700 may include operation structures including the operation structure 710, interface structures including the first interface structure 720 and the second interface structure 730, and multi-face connection structures including the multi-face connection structure 740. The operation structures, the interface structures, and the multi-face connection structures may form a repetitive three-dimensional pattern in the semiconductor structure 700. The repetitive three-dimensional pattern may form a fractal structure. The repetitive three-dimensional pattern may include sub-patterns including the operation structures, the interface structures, and the multi-face connection structures in different combination ratios. The operation structure 710, the first interface structure 720, the second interface structure 730, and the multi-face connection structure 740 of FIG. 7 may be one sub-pattern of the repetitive three-dimensional pattern.

For example, the repetitive three-dimensional pattern may include one or more from among a first sub-pattern in which a first interface structure among the interface structures is connected to one of the faces of a first multi-face connection structure among the multi-face connection structures, and first operation structures among the operation structures are connected to the remaining faces, excluding the one, of the faces of the first multi-face connection structure; a second sub-pattern in which second interface structures among the interface structures are connected to two of the faces of a second multi-face connection structure among the multi-face connection structures, and second operation structures among the operation structures are connected to the remaining faces, excluding the two, of the faces of the second multi-face connection structure; a third sub-pattern in which third interface structures among the interface structures are connected to all faces of a third multi-face connection structure among the multi-face connection structures; and a fourth sub-pattern in which a fourth operation structure among the operation structures is connected to one of faces of a fourth multi-face connection structure among the multi-face connection structures, and fourth interface structures among the interface structures are connected to the remaining faces, excluding the one, of the faces of the fourth multi-face connection structure. However, the first sub-pattern, the second sub-pattern, the third sub-pattern, and the fourth sub-pattern are examples, and sub-patterns are not limited thereto.

The combination of the operation structure 710, the first interface structure 720, the second interface structure 730, and the multi-face connection structure 740 of FIG. 7 is just an example, and examples are not limited thereto. For example, the semiconductor structure 700 may include a first operation structure including a first multi-face structure and operation chips, in which a first signal path is formed inside the first multi-face structure and the operation chips are arranged on faces of the first multi-face structure and are connected to the first signal path; a second operation structure including a second multi-face structure and operation chips, in which a second signal path is formed inside the second multi-face structure and the operation chips are arranged on faces of the second multi-face structure and are connected to the second signal path; and a first multi-face connection structure that contacts a first connection face among the faces of the first multi-face structure and a second connection face among the faces of the second multi-face structure to connect a third signal path to the first signal path and the second signal path, in which the third signal path is formed inside the multi-face connection structure.

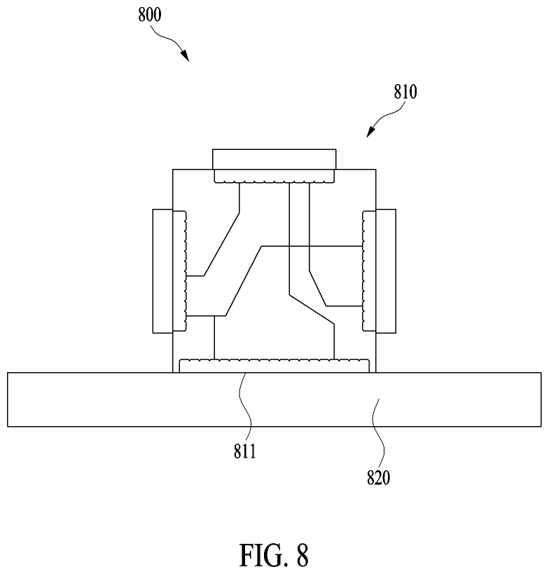

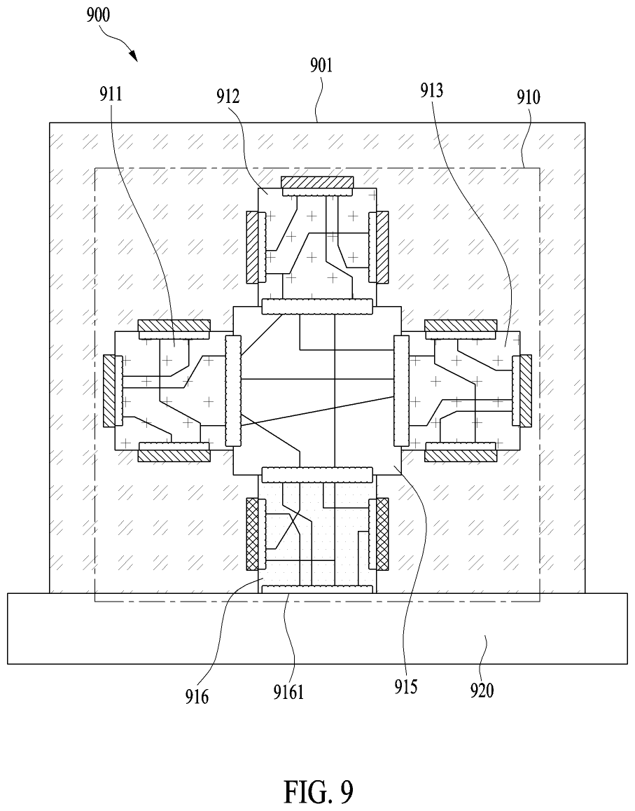

FIGS. 8 and 9 are diagrams each illustrating an example of a configuration and a structure of a semiconductor package, according to an embodiment. Referring to FIG. 8, a semiconductor package 800 may include a unit structure 810 and a substrate 820. The unit structure 810 may be connected to the substrate 820 through a connection face 811. A multi-face structure of the unit structure 810 may perform an interposer role, compared to the substrate 820, but examples are not limited thereto. A unit structure 810 may be one from among an operation structure, an interface structure, and a multi-face connection structure. One or more of operation structures, interface structures, and multi-face connection structures, like the unit structure 810, may be connected to the substrate 820. The unit structure 810 may be connected to one or more of other unit structures.

Referring to FIG. 9, a semiconductor package 900 may include a semiconductor structure 910 and a substrate 920. The semiconductor structure 910 may include operation structures 911, 912, and 913, an interface structure 916, and a multi-face connection structure 915. The multi-face connection structure 915 may connect the operation structures 911, 912, and 913 and may be connected to the interface structure 916. The interface structure 916 may be connected to the substrate 920 through a connection face 9161.

The semiconductor package 900 may include a cooling region 901. The cooling region 901 may be a space formed by a physical barrier. A heat transmission medium in a gas form and/or a liquid form may be provided in the cooling region 901. In the semiconductor structure 910, a space may be formed between structures, such as the operation structures 911, 912, and 913, the interface structure 916, and the multi-face connection structure 915. The heat transmission medium provided in this space may cool the structures.

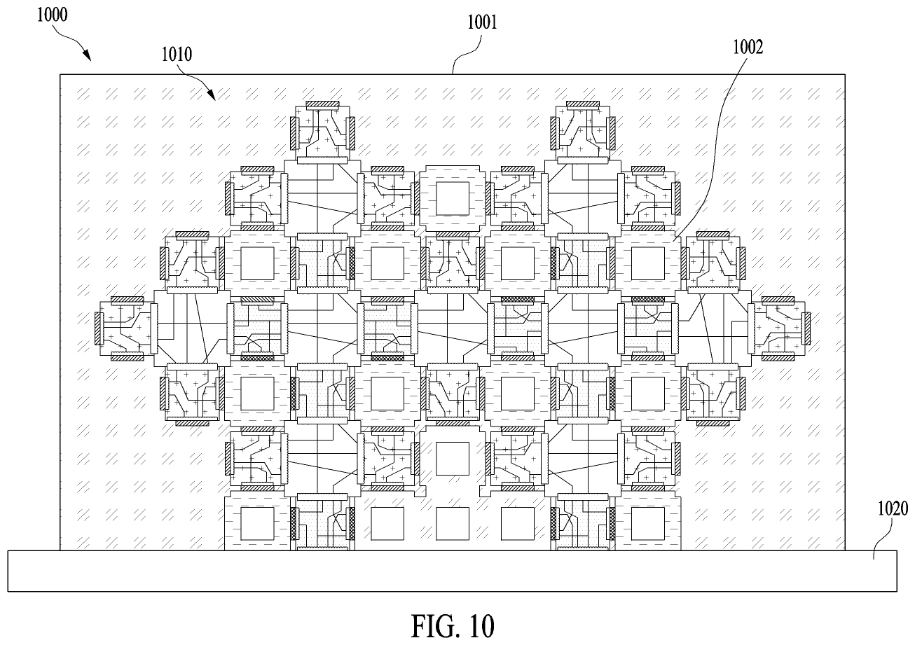

FIG. 10 is a diagram illustrating an example of a cooling tunnel, according to an embodiment. Referring to FIG. 10, a semiconductor package 1000 may include a semiconductor structure 1010 and a substrate 1020. The semiconductor package 1000 may include a cooling region 1001. A space may be formed between operation structures, interface structures, and multi-face connection structures of the semiconductor structure 1010. A cooling tunnel 1002 may be provided in this space. The cooling tunnel 1002 may be a physical barrier. A heat transmission medium may pass through the cooling tunnel 1002. The heat transmission medium may cool structures, such as the operation structures, the interface structures, and the multi-face connection structures, of the semiconductor structure 1010.

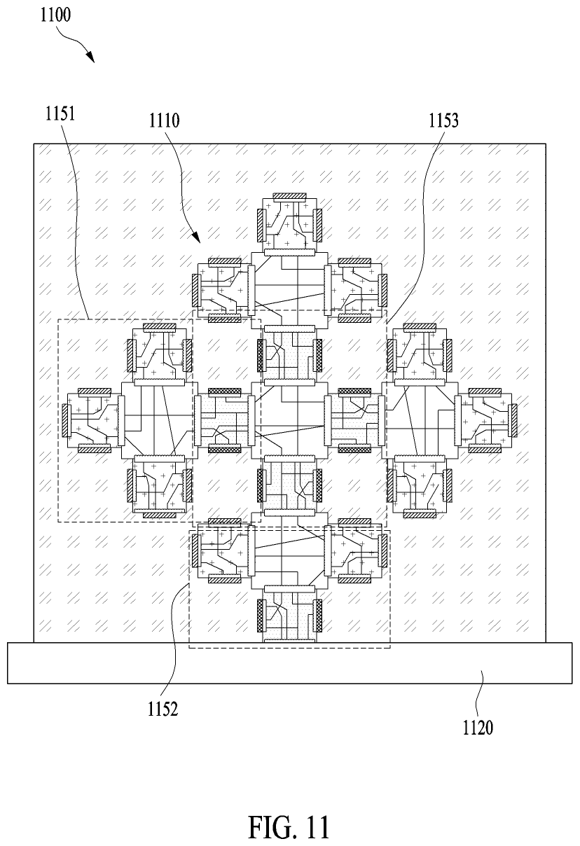

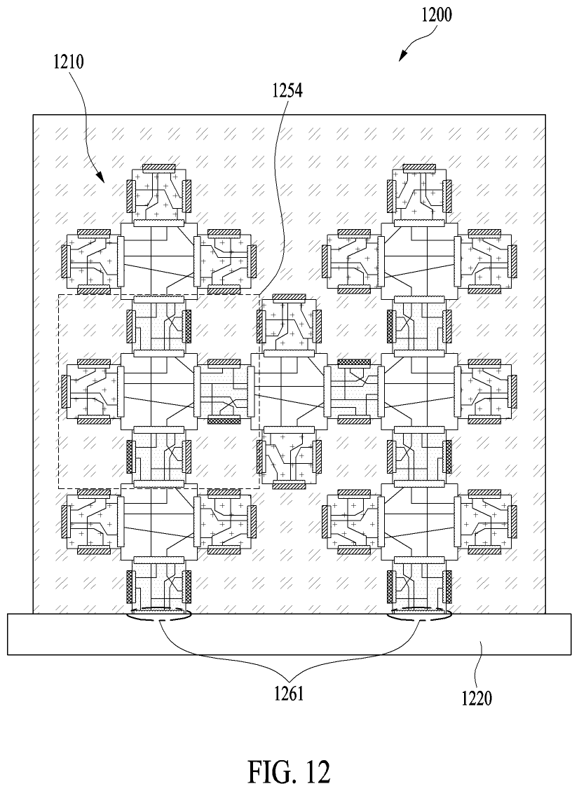

FIGS. 11 and 12 are diagrams each illustrating an example of sub-patterns of a repetitive three-dimensional pattern, according to an embodiment. Referring to FIG. 11, a semiconductor package 1100 may include a semiconductor structure 1110 and a substrate 1120. The semiconductor structure 1110 may include operation structures, interface structures, and multi-face connection structures. The operation structures, the interface structures, and the multi-face connection structures may form a repetitive three-dimensional pattern in the semiconductor structure 1110. The repetitive three-dimensional pattern may include sub-patterns including the operation structures, the interface structures, and the multi-face connection structures in different combination ratios.

For example, the semiconductor structure may include a first sub-pattern 1151, a second sub-pattern 1152, and a third sub-pattern 1153. In the first sub-pattern 1151, a first interface structure among the interface structures may be connected to one of the faces of a first multi-face connection structure among the multi-face connection structures, and first operation structures among the operation structures may be connected to the remaining faces, excluding the one, of the faces of the first multi-face connection structure. In the second sub-pattern 1152, second interface structures among the interface structures may be connected to two of the faces of a second multi-face connection structure among the multi-face connection structures, and second operation structures among the operation structures may be connected to the remaining faces, excluding the two, of the faces of the second multi-face connection structure. In the third sub-pattern 1153, third interface structures among the interface structures may be connected to all faces of a third multi-face connection structure among the multi-face connection structures.

Referring to FIG. 12, a semiconductor package 1200 may include a semiconductor structure 1210 and a substrate 1220. The semiconductor structure 1210 may include operation structures, interface structures, and multi-face connection structures. The operation structures, the interface structures, and the multi-face connection structures may form a repetitive three-dimensional pattern in the semiconductor structure 1110. For example, the repetitive three-dimensional pattern may include a fourth sub-pattern 1254 in which a fourth operation structure among the operation structures is connected to one of faces of a fourth multi-face connection structure among the multi-face connection structures, and fourth interface structures among the interface structures are connected to the remaining faces, excluding the one, of the faces of the fourth multi-face connection structure.

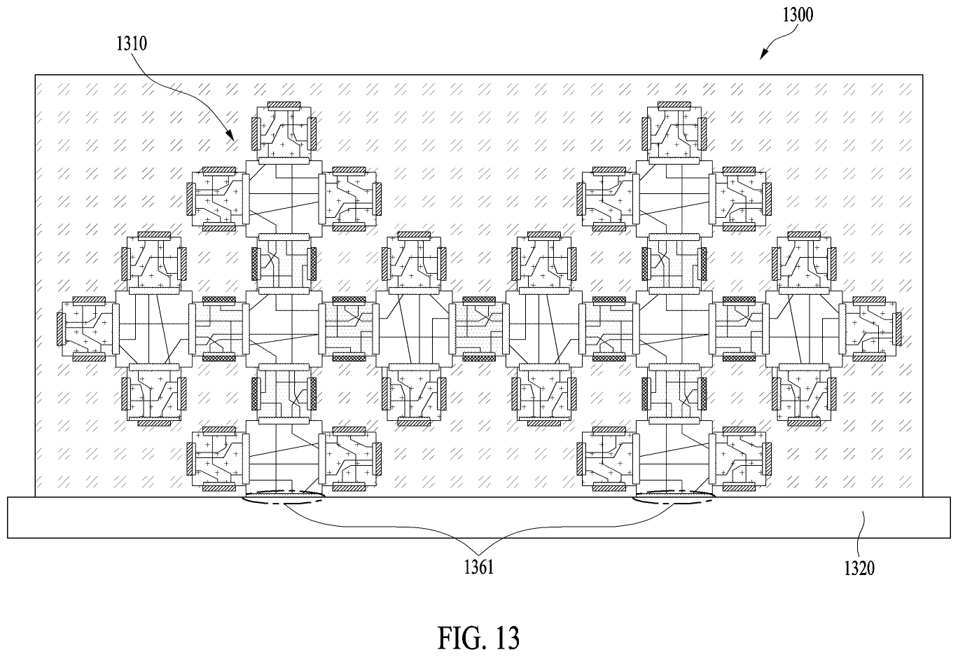

In the semiconductor structure 1210, repetitive sub-patterns may form groups. Each group may have one or more connection points with the substrate 1220. FIG. 12 illustrates the example of a sub-pattern group of the semiconductor structure 1210 forming a multi-connection 1261 with the substrate 1220. The multi-connection 1261 may improve connection strength between the sub-pattern group and the substrate 1220 and may increase the communication bandwidth between the sub-pattern group and the substrate 1220. For example, with reference to FIG. 13, the multi-connection 1261 may be provided by at least two interface structures being connected to the substrate 1220 through respective connection faces.

FIG. 13 is a diagram illustrating an example of multi-connection between a semiconductor structure and a substrate, according to an embodiment. Referring to FIG. 13, a semiconductor package 1300 may include a semiconductor structure 1310 and a substrate 1320. The semiconductor structure 1310 may form a multi-connection 1361 with the substrate 1320. According to the example of FIG. 12, the multi-connection 1261 may be formed by using the interface structures of the semiconductor structure 1210. According to the example of FIG. 13, the multi-connection 1361 may be formed by using the multi-face connection structures of the semiconductor structure 1310.

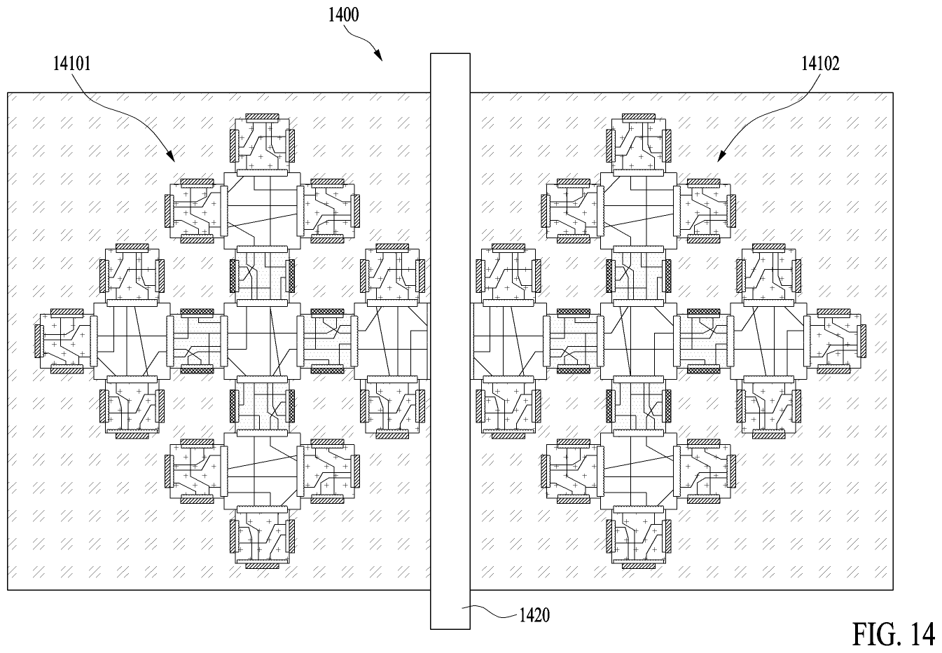

FIG. 14 is a diagram illustrating an example of semiconductor structures arranged on opposite sides of a substrate, according to an embodiment. Referring to FIG. 14, a semiconductor package 1400 may include a first semiconductor structure 14101, a second semiconductor structure 14102, and a substrate 1420. The first semiconductor structure 14101 and the second semiconductor structure 14102 may be connected to opposite faces of the substrate 1420, respectively. The first semiconductor structure 14101 may be connected to one side of the substrate 1420, and the second semiconductor structure 14102 may be connected to the other side of the substrate 1420. The one side and the other side may be opposite sides of the substrate 1420.

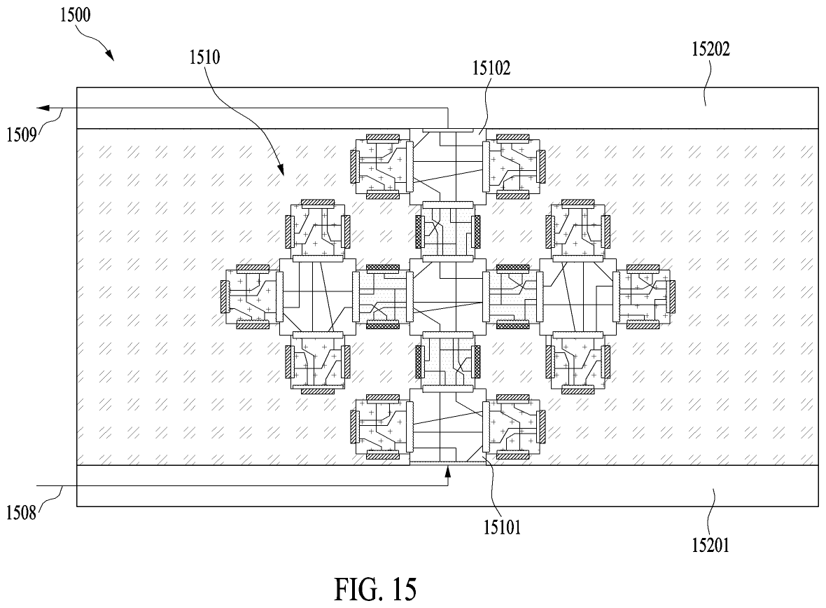

FIG. 15 is a diagram illustrating an example of a semiconductor structure connected to a plurality of substrate regions, according to an embodiment. Referring to FIG. 15, a semiconductor package 1500 may include a semiconductor structure 1510, a first substrate region 15201, and a second substrate region 15202. The semiconductor structure 1510 may include a first structure 15101 and a second structure 15102. The semiconductor structure 1510 may include operation structures, interface structures, and multi-face connection structures. The first structure 15101 and the second structure 15102 may each be one from among the operation structures, the interface structures, and the multi-face connection structures. FIG. 15 illustrates the example of each of the first structure 15101 and the second structure 15102 being a multi-face connection structure, but examples are not limited thereto.

The first structure 15101 may be connected to the first substrate region 15201, and the second structure 15102 may be connected to the second substrate region 15202. The semiconductor structure 1510 may be connected to the first substrate region 15201 and the second substrate region 15202 through the first structure 15101 and the second structure 15102, respectively. The first substrate region 15201 and the second substrate region 15202 may belong to the same substrate or different substrates. For example, the first substrate region 15201 and the second substrate region 15202 may belong to a first substrate. For example, the first substrate region 15201 may belong to the first substrate, and the second substrate region 15202 may belong to a second substrate.

Different substrate regions, such as the first substrate region 15201 and the second substrate region 15202, may be used for different data flows. For example, input data 1508 may be input to the semiconductor structure 1510 through the first substrate region 15201 and the first structure 15101. The semiconductor structure 1510 may process the input data 1508 by using unit structures. Output data 1509 of the semiconductor structure 1510 may be output through the second structure 15102 and the second substrate region 15202. Efficient data flows may be induced by input/output through different points.

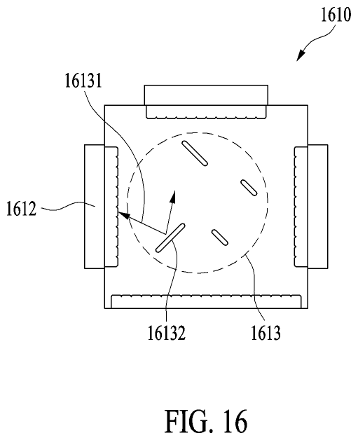

FIG. 16 is a diagram illustrating an example of a unit structure including an optical signal path, according to an embodiment. Referring to FIG. 16, a unit structure 1610 may include a signal path 1613 therein. In the example of FIG. 16, the signal path 1613 may include an optical path. For example, the signal path 1613 may include a micro-reflector 16132 to form the optical path. For example, when an optical signal 16131 is input to a chip 1612, the micro-reflector 16132 may reflect the optical signal 16131 onto the chip 1612. When the optical signal 16131 is output from the chip 1612, the micro-reflector 16132 may reflect the optical signal 16131 onto another chip or a connection face of the unit structure 1610. The optical signal 16131 reflected onto the connection face may be transmitted to another unit structure or a substrate. A signal converter for converting signals between an electrical signal and the optical signal 16131 may be provided in a chip region of the chip 1612 and/or the unit structure 1610.

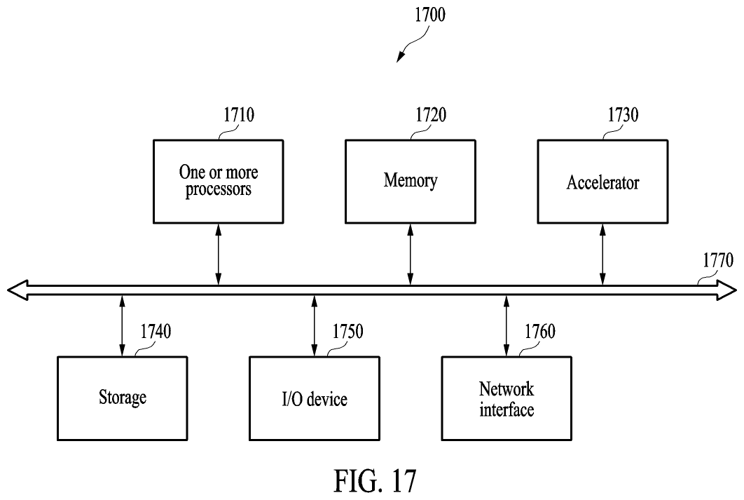

FIG. 17 is a diagram illustrating an example of a configuration of an electronic device, according to an embodiment. Referring to FIG. 17, an electronic device 1700 may include one or more processors 1710, a memory 1720, an accelerator 1730, a storage 1740, an input/output (I/O) device 1750, and a network interface 1760. These components may communicate with each other via a communication bus 1770.

The one or more processors 1710 may execute instructions stored in the memory 1720 or the storage 1740. The instructions, when executed by the one or more processors 1710, may operate the electronic device 1700. The memory 1720 may include a non-transitory computer-readable storage medium or a non-transitory computer-readable storage device. The memory 1720 may store instructions to be executed by the one or more processors 1710 and may store related information while software and/or an application is being executed by the electronic device 1700.

The accelerator 1730 may process a large-scale operation, such as an AI operation. The accelerator 1730 may include a memory structure in a fractal structure in an embodiment. For example, a semiconductor structure may include an operation structure, an interface structure, and a multi-face connection structure. Operation structures, interface structures, and multi-face connection structures may form a repetitive three-dimensional pattern in the semiconductor structure. The accelerator 1730 may receive input data from the one or more processors 1710, may perform an AI operation based on the input data, and may provide output data from the AI operation to the one or more processors 1710.

The storage 1740 may include a computer-readable storage medium or a computer-readable storage device. The storage 1740 may store more information than the memory 1720 for a long time. For example, the storage 1740 may include a magnetic hard disk, an optical disc, a flash memory, a floppy disk, or other non-volatile memories.

The I/O device 1750 may receive an input from the user in traditional input manners through a keyboard and a mouse, and in new input manners, such as a touch input, a voice input, and an image input. For example, the I/O device 1750 may include a keyboard, a mouse, a touch screen, a microphone, or any other device that detects the input from the user and transmits the detected input to the electronic device 1700. The I/O device 1750 may provide an output of the electronic device 1700 to the user through a visual, auditory, or haptic channel. The I/O device 1750 may include, for example, a display, a touch screen, a speaker, a vibration generator, or any other device that provides the output to the user. The network interface 1760 may communicate with an external device through a wired or wireless network.

The units described herein may be implemented using a hardware component, a software component and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor, or any other device capable of responding to and executing instructions in a defined manner. The processing device may run an operating system (OS) and one or more software applications that run on the OS. The processing unit also may access, store, manipulate, process, and generate data in response to execution of the software. For purpose of simplicity, the description of a processing unit is used as singular; however, one skilled in the art will appreciate that a processing unit may include multiple processing elements and multiple types of processing elements. For example, the processing unit may include a plurality of processors, or a single processor and a single controller. In addition, different processing configurations are possible, such as parallel processors.

The software may include a computer program, a piece of code, an instruction, or some combination thereof, to independently or collectively instruct or configure the processing unit to operate as desired. Software and data may be stored in any type of machine, component, physical or virtual equipment, or computer storage medium or device capable of providing instructions or data to or being interpreted by the processing unit. The software also may be distributed over network-coupled computer systems so that the software is stored and executed in a distributed fashion. The software and data may be stored by one or more non-transitory computer-readable recording mediums.

The methods according to the above-described examples may be recorded in non-transitory computer-readable media including program instructions to implement various operations of the above-described examples. The media may also include, alone or in combination with the program instructions, data files, data structures, and the like. The program instructions recorded on the media may be those specially designed and constructed for the purposes of examples, or they may be of the kind well-known and available to those having skill in the computer software arts. Examples of non-transitory computer-readable media include magnetic media such as hard disks, floppy disks, and magnetic tape; optical media such as CD-ROM discs and DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher-level code that may be executed by the computer using an interpreter.

The above-described devices may act as one or more software modules in order to perform the operations of the above-described examples, or vice versa.

Although non-limiting example embodiments have been described above with reference to the drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the present disclosure.

What is claimed is:

1. A semiconductor structure comprising:
at least one operation structure comprising a first multi-face structure and operation chips, wherein the first multi-face structure comprises a first signal path, and the operation chips are on faces of the first multi-face structure and are connected to the first signal path;
at least one interface structure comprising a second multi-face structure and interface chips, wherein the second multi-face structure comprises a second signal path, and the interface chips are on faces of the second multi-face structure and are connected to the second signal path; and
at least one multi-face connection structure that contacts a first connection face from among the faces of the first multi-face structure and a second connection face from among the faces of the second multi-face structure,
wherein the at least one multi-face connection structure comprises a third signal path that is connected to the first signal path of an operation structure, from among the at least one operation structure, and the second signal path of an interface structure, from among the at least one interface structure.

2. The semiconductor structure of claim 1, wherein
the at least one operation structure is a plurality of operation structures,
the at least one interface structure is a plurality of interface structures,
the at least one multi-face connection structure is a plurality of multi-face connection structures, and
the plurality of operation structures, the plurality of interface structures, and the plurality of multi-face connection structures form a repetitive three-dimensional pattern in the semiconductor structure.

3. The semiconductor structure of claim 2, wherein the repetitive three-dimensional pattern comprises sub-patterns comprising the plurality of operation structures, the plurality of interface structures, and the plurality of multi-face connection structures in different combination ratios.

4. The semiconductor structure of claim 2, wherein the repetitive three-dimensional pattern comprises:
a first sub-pattern in which a first interface structure from among the plurality of interface structures is connected to one of the faces of a first multi-face connection structure from among the plurality of multi-face connection structures, and first operation structures from among the plurality of operation structures are connected to remaining faces, excluding the one, of the faces of the first multi-face connection structure;
a second sub-pattern in which second interface structures from among the plurality of interface structures are connected to two of the faces of a second multi-face connection structure from among the plurality of multi-face connection structures, and second operation structures from among the plurality of operation structures are connected to remaining faces, excluding the two, of the faces of the second multi-face connection structure;
a third sub-pattern in which third interface structures from among the plurality of interface structures are connected to all faces of a third multi-face connection structure from among the plurality of multi-face connection structures; and
a fourth sub-pattern in which a fourth operation structure from among the plurality of operation structures is connected to one of faces of a fourth multi-face connection structure from among the plurality of multi-face connection structures, and fourth interface structures from among the plurality of interface structures are connected to remaining faces, excluding the one, of the faces of the fourth multi-face connection structure.

5. The semiconductor structure of claim 2, further comprising a substrate,
wherein one or more from among the plurality of operation structures, the plurality of interface structures, and the plurality of multi-face connection structures are connected to the substrate.

6. The semiconductor structure of claim 2, further comprising a first substrate region and a second substrate region,
wherein a first structure from among the plurality of operation structures, the plurality of interface structures, and the plurality of multi-face connection structures is connected to the first substrate region,
wherein a second structure from among the plurality of operation structures, the plurality of interface structures, and the plurality of multi-face connection structures is connected to the second substrate region, and
wherein the first structure is configured to receive first data through the first substrate region, and the second structure is configured to output second data to the second substrate region.

7. The semiconductor structure of claim 2, further comprising a cooling tunnel in a space between the plurality of operation structures, the plurality of interface structures, and the plurality of multi-face connection structures.

8. The semiconductor structure of claim 1, wherein
the operation chips are connected to the first connection face through the first signal path,
the interface chips are connected to the second connection face through the second signal path, and
the operation chips are connected to the interface chips through the first signal path, the second signal path, and the third signal path.

9. The semiconductor structure of claim 1, wherein one or more from among the first signal path, the second signal path, and the third signal path comprise one or more from among a wired path, a wireless path, and an optical path.

10. The semiconductor structure of claim 1, wherein
the operation chips are configured to perform one or more from among an operation function and a memory function, and
the interface chips are configured to perform one or more from among a communication function and a power function.

11. The semiconductor structure of claim 1, wherein the first multi-face structure, the second multi-face structure, and the at least one multi-face connection structure each have a cube shape.

12. A semiconductor package comprising:
at least one substrate; and
a semiconductor structure comprising operation structures, interface structures, and multi-face connection structures,
wherein one or more from among the operation structures, the interface structures, and the multi-face connection structures are connected to a substrate,
wherein the operation structures, the interface structures, and the multi-face connection structures form a repetitive three-dimensional pattern,
wherein an operation structure from among the operation structures comprises a first multi-face structure and operation chips on faces of the first multi-face structure,
wherein an interface structure from among the interface structures comprises a second multi-face structure and interface chips that are on faces of the second multi-face structure, and
wherein a multi-face connection structure from among the multi-face connection structures is connected to the operation structure and the interface structure through a first connection face from among the faces of the first multi-face structure and a second connection face from among the faces of the second multi-face structure.

13. The semiconductor package of claim 12, wherein the repetitive three-dimensional pattern comprises sub-patterns comprising the operation structures, the interface structures, and the multi-face connection structures in different combination ratios.

14. The semiconductor package of claim 12, wherein the repetitive three-dimensional pattern comprises:
a first sub-pattern in which a first interface structure from among the interface structures is connected to one of the faces of a first multi-face connection structure from among the multi-face connection structures, and first operation structures from among the operation structures are connected to remaining faces, excluding the one, of the faces of the first multi-face connection structure;
a second sub-pattern in which second interface structures from among the interface structures are connected to two of the faces of a second multi-face connection structure from among the multi-face connection structures, and second operation structures from among the operation structures are connected to remaining faces, excluding the two, of the faces of the second multi-face connection structure;
a third sub-pattern in which third interface structures from among the interface structures are connected to all faces of a third multi-face connection structure from among the multi-face connection structures; and
a fourth sub-pattern in which a fourth operation structure from among the operation structures is connected to one of faces of a fourth multi-face connection structure from among the multi-face connection structures, and fourth interface structures from among the interface structures are connected to remaining faces, excluding the one, of the faces of the fourth multi-face connection structure.

15. The semiconductor package of claim 12, wherein
a first structure from among the operation structures, the interface structures, and the multi-face connection structures is connected to a first substrate region of the at least one substrate, and
a second structure from among the operation structures, the interface structures, and the multi-face connection structures is connected to a second substrate region of the at least one substrate,
wherein the first structure is configured to receive first data through the first substrate region, and the second structure is configured to output second data to the second substrate region.

16. The semiconductor package of claim 12, further comprising a cooling tunnel in a space between the operation structures, the interface structures, and the multi-face connection structures.

17. The semiconductor package of claim 12, wherein
the first multi-face structure comprises a first signal path that is connected to the operation chips,
the second multi-face structure comprises a second signal path that is connected to the interface chips, and
the multi-face connection structure comprises a third signal path.

18. The semiconductor package of claim 17, wherein
the operation chips are connected to the first connection face through the first signal path,
the interface chips are connected to the second connection face through the second signal path, and
the operation chips are connected to the interface chips through the first signal path, the second signal path, and the third signal path.

19. The semiconductor package of claim 17, wherein one or more from among the first signal path, the second signal path, and the third signal path comprise one or more from among a wired path, a wireless path, and an optical path.

20. A semiconductor structure comprising:
a first operation structure comprising a first multi-face structure and first operation chips, wherein the first multi-face structure comprises a first signal path, and the first operation chips are on faces of the first multi-face structure and are connected to the first signal path;
a second operation structure comprising a second multi-face structure and second operation chips, wherein the second multi-face structure comprises a second signal path, and the second operation chips are on faces of the second multi-face structure and are connected to the second signal path; and
a multi-face connection structure that contacts a first connection face from among the faces of the first multi-face structure and a second connection face from among the faces of the second multi-face structure,
wherein the multi-face connection structure comprises a third signal path that is connected to the first signal path and the second signal path.
